(19) United States
(12) Patent Application Publication
(10) Pub. No.: US 2024/0395553 A1
(43) Pub. Date: Nov. 28, 2024

(54) HIGH ASPECT RATIO JUNCTION FORMATION THROUGH GAS PHASE DOPING

(71) Applicant: Applied Materials, Inc., Santa Clara, CA (US)

(72) Inventors: Zhijun Chen, San Jose, CA (US); Fredrick Fishburn, Aptos, CA (US); In Soo Jung, Campbell, CA (US); Zuoming Zhu, Sunnyvale, CA (US)

(73) Assignee: Applied Materials, Inc., Santa Clara, CA (US)

(21) Appl. No.: 18/659,219

(22) Filed: May 9, 2024

Related U.S. Application Data
(60) Provisional application No. 63/504,118, filed on May 24, 2023.

(51) Int. Cl. H01L 21/223; H01L 21/02; H10B 12/00

(52) U.S. Cl. CPC H01L 21/223; H01L 21/02057; H10B 12/00

(57) ABSTRACT

Semiconductor processing methods and semiconductor structures are provided with improved doping in target regions. Methods include providing a substrate disposed within a semiconductor processing chamber, where one or more undoped target regions are formed on the substrate. Methods include subjecting the one or more undoped target regions to a pre-clean operation, removing at least a portion of any oxide present on the one or more undoped target regions. Methods include contacting the one or more undoped target regions with a gas phase dopant or a radical thereof, doping the one or more target regions.

### CROSS-REFERENCE TO RELATED APPLICATION

This application claims the benefit of U.S. Provisional No. 63/504,118 filed on May 24, 2023, entitled “HIGH ASPECT RATIO JUNCTION FORMATION THROUGH GAS PHASE DOPING,” the entire contents of which are incorporated herein by reference.

### TECHNICAL FIELD

The present technology relates to deposition and removal processes and chambers. More specifically, the present technology relates to systems and methods enhancing doping into a silicon material through gas phase doping.

### BACKGROUND

Integrated circuits are made possible by processes which produce intricately patterned material layers on substrate surfaces. Producing patterned material on a substrate requires controlled methods for forming and removing material. Material characteristics may affect how the device operates, and may also affect how the films are removed relative to one another. Deposition processes produce films having certain characteristics. Many films that are formed require additional processing to adjust or enhance the material characteristics of the film in order to provide suitable properties.

Thus, there is a need for improved systems and methods that can be used to produce high quality devices and structures. These and other needs are addressed by the present technology.

### BRIEF SUMMARY

The present technology is generally directed to semiconductor processing methods and structures. Methods include providing a high aspect ratio semiconductor structure within a semiconductor processing chamber, where one or more undoped target regions are formed on the semiconductor structure. Methods include subjecting the one or more undoped target region to a pre-clean operation, removing at least a portion of any oxide present on the one or more undoped target regions. Methods include contacting the one or more undoped target regions with a gas phase dopant or a radical thereof and doping the one or more target regions.

In embodiments, methods include where a temperature within the semiconductor processing chamber or a temperature of the substrate is maintained at greater than or about 600° C. In more embodiments, methods include where the target region is disposed in a recess located within the semiconductor structure, and/or where the target region is disposed within a feature having a width of 10 nm or less. In further embodiments, less than or about 5 wt. % of total oxide remains in the target region subsequent the pre-clean operation, based upon a weight of the target region. Additionally or alternatively, in embodiments, an oxygen free atmosphere is maintained within the semiconductor processing chamber curing the pre-clean operation, and during the contact with the gas phase dopant. In more embodiments, the pre-clean operation is integrated into the semiconductor processing chamber. In embodiments, the gas phase dopant comprises phosphine (PH₃), arsine (AsH₃), nitrogen, (N₂), ammonia (NH₃), germane (GeH₄), borane (BH₃), diborane (B₂H₆), trimethyl gallium (Ga(CH₃)₃), aluminum chloride (AlCl₃), trimethylaluminum (C₆Hl₅Al), radicals thereof, or combinations thereof. Moreover, in embodiments, the gas phase dopant is a phosphorus containing gas, a borane containing gas, radicals thereof, or a combination thereof. Furthermore, in embodiments, methods include doping all or a portion of the semiconductor structure with an epitaxial doping deposition or an implant prior to or subsequent the gas phase doping.

The present technology is generally directed to semiconductor structures. Structures include at least one channel, a junction disposed on an end of the channel, the junction having an exposed surface and an interior end adjacent to the channel. Junctions include a layer adjacent to the exposed surface, or forming the exposed surface, where the layer includes a dopant concentration at any point along the layer or surface that is greater than or about 50% of an average doping concentration of the layer. Structures include where the exposed surface has a doping level higher than a doping level of the interior end, and where the channel is disposed adjacent to a feature having an aspect ratio of greater than or about 50 or a feature width of less than 10 nm, or where the at least one channel is disposed in a recess within the semiconductor structure.

In embodiments, junctions include where the exposed surface has a doping concentration of greater than or about 1×10¹⁹ atoms/cm³. In embodiments, the interior end has a doping concentration of greater than or about 1×10¹⁸ atoms/cm³. In yet another embodiment, the junction defines a junction length between the exposed surface and the interior end, where the length is greater than or about 40 nm. In further embodiments, the junction includes less than or about 2 wt. % total oxides based upon a weight of the junction. In another embodiment, the junction is substantially free of total oxides.

The present technology is also generally directed to memory devices. Memory devices include a bit line extending in a first direction, two or more word lines extending in a second direction different than the first direction, at least one channel, and at least one junction disposed on a second end of the channel. Channels extend between adjacent word lines in a direction generally orthogonal to the first direction and the second direction, and have a first end adjacent to the bit line and a second end opposite the first end. Memory devices include where the at least one junction includes a dopant concentration of greater than or about 1×10¹⁸ atoms/cm³, and include less than or about 5 wt. % total oxides based upon a weight of the junction.

In embodiments, memory devices are a 3D DRAM device and/or a 4F2 device. In further embodiments, the junction is disposed adjacent to a feature having a width of less than or about 10 nm. In yet more embodiments, the junction has a length from an exposed surface to an interior end of greater than or about 40 nm.

Such technology may provide numerous benefits over conventional processing methods. For example, gas phase doping as discussed herein may provide for the doping of high aspect ratio junctions. In addition, processes and methods discussed herein may provide for the doping of non line-of-sight junctions (e.g. recessed structures). Additionally, the doping processes and methods discussed herein may provide dopant levels higher than those achievable utilizing solid state doping with high aspect ratio structures or recessed structures. Processes and methods discussed herein may also achieve such doping levels without requiring additional epitaxial growth and etch back operations, reducing process steps and preventing damage to high aspect ratio features. These and other embodiments, along with many of their advantages and features, are described in more detail in conjunction with the below description and attached figures.

### BRIEF DESCRIPTION OF THE DRAWINGS

A further understanding of the nature and advantages of the disclosed technology may be realized by reference to the remaining portions of the specification and the drawings.

FIG. 1 shows a top plan view of an exemplary processing system according to embodiments of the present technology.

FIG. 2 shows a schematic cross-sectional view of an exemplary plasma system according to embodiments of the present technology.

FIG. 3 shows operations of an exemplary method of semiconductor processing according to embodiments of the present technology.

FIGS. 4A and 4B show cross-sectional views of a semiconductor structure according to embodiments of the present technology.

FIGS. 5A and 5B show cross-sectional views of a semiconductor structure according to embodiments of the present technology.

Several of the figures are included as schematics. It is to be understood that the figures are for illustrative purposes and are not to be considered of scale unless specifically stated to be of scale. Additionally, as schematics, the figures are provided to aid comprehension and may not include all aspects or information compared to realistic representations and may include exaggerated material for illustrative purposes.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION

As the DRAM industry moves from planar 6F2 schemes to 4F2 vertical channel transistors schemes or 3D DRAM, the need for high aspect ratio processes increases significantly. In addition, the evolving transistor schemes have also developed devices with one or more recesses from a main channel, causing non-line-of-sight features to evolve. For instance, during 3D DRAM processing, silicon channels are formed when other materials, such as silicon nitride and silicon oxide form high aspect ratio features with silicon material, such as the substrate, forming a lower end of the features. In subsequent processing, source and drain regions are formed by doping underlying silicon-containing materials. Subsequent processing may form contacts on the source and drain regions.

Conventional doping of silicon-containing materials in high aspect ratio structures may be done by selective epitaxial growth of doped silicon on the silicon-containing materials (laterally or vertically placed), plasma implant processes, or a solid-phase doping processes, such as conformal deposition of a dopant containing film and a drive in anneal operation followed by removal of the dopant containing film. Depending on the specific design of the device, the silicon may be doped to be p-type or n-type silicon. A portion of the dopant in the epitaxially grown doped silicon or implant may travel into the underlying silicon-containing materials, thereby doping the underlying silicon-containing materials. However, as device complexity and aspect ratios increase, in conjunction with growing demand for high quality structures, these conventional technologies may not provide adequate doping depths, concentrations, and/or uniformity.

Additionally, conventional technologies deposit byproduct materials elsewhere on the structures that may frustrate subsequent processing, requiring intermediate processing to remove the byproduct material, or reduce final device function. Specifically, when solid phase doping is used, it can be difficult to remove some or all of the dopant containing film after the drive-in anneal, particularly without damaging the underlying channels. Namely, removing the deposited material without removing the now doped silicon has proven challenging. Thus, current processes are problematic, particularly for thin channels, such as channels having a width of less than 10 nm, and other high aspect ratio channels, as they frequently result in damage to the channel, resulting in decreases in electrical properties. Even if it is possible to fully remove the implanted or deposited materials, it can be a costly, time consuming process, and wasteful process.

In addition, existing plasma processes require line-of-sight from the plasma source to the targeted doping region. This is problematic for structures that have corners or angled walls separating channels from central apertures (e.g. recessed devices). For instance, 3D DRAM structures which have vertically extending holes and a plurality of channels recessing horizontally from the vertically extending hole. Thus, existing plasma technology is not capable of doping regions within the horizontal channels, due to the lack of linear pathway to the plasma source.

The present technology has surprisingly found that by carefully pre-treating the target junction region and utilizing tailored processing conditions, gas phase doping may be utilized to precisely and robustly dope high aspect ratio channels and non-line-of-sight junction regions, overcoming these and other problems. Namely, without wishing to be bound by theory, the present technology has found that by carefully removing substantially all or all oxide present, including native oxide, junction regions may be doped utilizing gas phase doping to yield high doping concentrations, such as higher doping concentrations than obtainable utilizing conventional techniques, in embodiments. Thus, the present technology may provide semiconductor components that have high levels of doping in one or more junction regions, with little to no oxide disposed within the junction, such as between a junction surface layer and a diffusion region. Moreover, such structures are exhibited even when the structure has a high aspect ratio, narrow channel, recessed surfaces, or a combination thereof.

Although the remaining disclosure will routinely identify specific deposition and etch processes utilizing the disclosed technology, it will be readily understood that the systems and methods are equally applicable to other deposition and etch chambers, as well as processes as may occur in the described chambers. Accordingly, the technology should not be considered to be so limited as for use with these specific deposition processes or chambers alone. The disclosure will discuss one possible system and chamber that may be used to perform deposition processes according to embodiments of the present technology before additional details according to embodiments of the present technology are described.

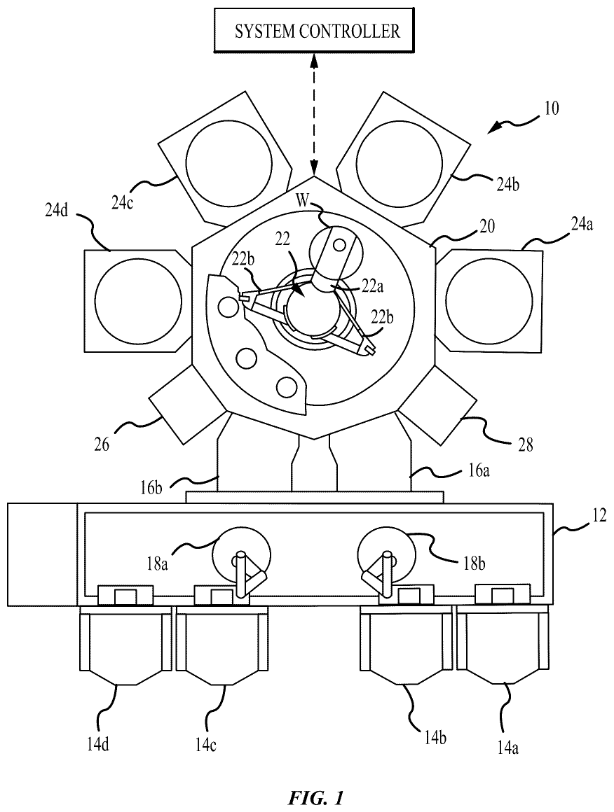

FIG. 1 shows a top plan view of one embodiment of a processing system 10 of deposition, etching, baking, and/or curing chambers according to embodiments. The tool or processing system 10 depicted in FIG. 1 may contain a plurality of process chambers, 24a-d, a transfer chamber 20, a service chamber 26, an integrated metrology chamber 28, and a pair of load lock chambers 16a-b. The process chambers may include any number of structures or components, as well as any number or combination of processing chambers.

To transport substrates among the chambers, the transfer chamber 20 may contain a robotic transport mechanism 22. The transport mechanism 22 may have a pair of substrate transport blades 22a attached to the distal ends of extendible arms 22b, respectively. The blades 22a may be used for carrying individual substrates to and from the process chambers. In operation, one of the substrate transport blades such as blade 22a of the transport mechanism 22 may retrieve a substrate W from one of the load lock chambers such as chambers 16a-b and carry substrate W to a first stage of processing, for example, a treatment process as described below in chambers 24a-d. The chambers may be included to perform individual or combined operations of the described technology. For example, while one or more chambers may be configured to perform a deposition or etching operation, one or more other chambers may be configured to perform a pre-treatment operation and/or one or more post-treatment operations described. Any number of configurations are encompassed by the present technology, which may also perform any number of additional fabrication operations typically performed in semiconductor processing.

If the chamber is occupied, the robot may wait until the processing is complete and then remove the processed substrate from the chamber with one blade 22a and may insert a new substrate with a second blade. Once the substrate is processed, it may then be moved to a second stage of processing. For each move, the transport mechanism 22 generally may have one blade carrying a substrate and one blade empty to execute a substrate exchange. The transport mechanism 22 may wait at each chamber until an exchange can be accomplished.

Once processing is complete within the process chambers, the transport mechanism 22 may move the substrate W from the last process chamber and transport the substrate W to a cassette within the load lock chambers 16a-b. From the load lock chambers 16a-b, the substrate may move into a factory interface 12. The factory interface 12 generally may operate to transfer substrates between pod loaders 14a-d in an atmospheric pressure clean environment and the load lock chambers 16a-b. The clean environment in factory interface 12 may be generally provided through air filtration processes, such as HEPA filtration, for example. Factory interface 12 may also include a substrate orienter/aligner that may be used to properly align the substrates prior to processing. At least one substrate robot, such as robots 18a-b, may be positioned in factory interface 12 to transport substrates between various positions/locations within factory interface 12 and to other locations in communication therewith. Robots 18a-b may be configured to travel along a track system within factory interface 12 from a first end to a second end of the factory interface 12.

The processing system 10 may further include an integrated metrology chamber 28 to provide control signals, which may provide adaptive control over any of the processes being performed in the processing chambers. The integrated metrology chamber 28 may include any of a variety of metrological devices to measure various film properties, such as thickness, roughness, composition, and the metrology devices may further be capable of characterizing grating parameters such as critical dimensions, sidewall angle, and feature height under vacuum in an automated manner.

Each of processing chambers 24a-d may be configured to perform one or more process steps in the fabrication of a semiconductor structure, and any number of processing chambers and combinations of processing chambers may be used on multi-chamber processing system 10.

For example, any of the processing chambers may be configured to perform a number of substrate processing operations including any number of deposition processes including cyclical layer deposition, atomic layer deposition, chemical vapor deposition, physical vapor deposition, as well as other operations including etch, pre-clean, pre-treatment, post-treatment, anneal, plasma processing, degas, orientation, and other substrate processes. Some specific processes that may be performed in any of the chambers or in any combination of chambers may be metal deposition, surface cleaning and preparation, thermal annealing such as rapid thermal processing, and plasma processing. Any other processes may similarly be performed in specific chambers incorporated into multi-chamber processing system 10, including any process described below, as would be readily appreciated by the skilled artisan.

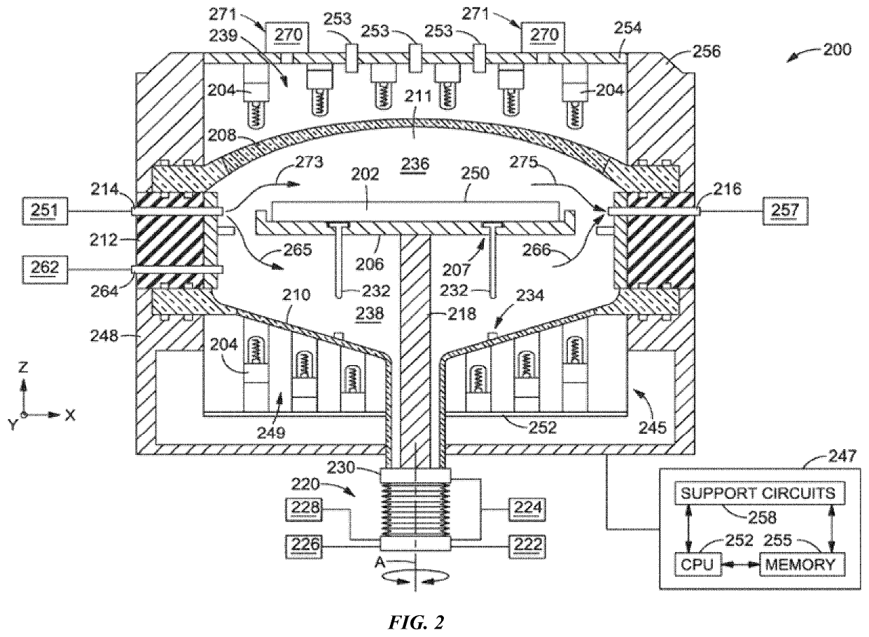

FIG. 2 illustrates a schematic cross-sectional view of an exemplary processing chamber 200 suitable for patterning a material layer disposed on a substrate 302, depositing one or more material layers, and/or providing one or more doping layers via gas phase doping as discussed herein, in the processing chamber 100. The process chamber 200 may be used to process one or more substrates therein, including the processes of depositing a material on a device side 250 of a substrate 202, heating of the substrate 202, etching of the substrate 202, or combinations thereof. The process chamber 200 may include a chamber wall 248, and an array of radiant heating lamps 204 for heating, among other components, a substrate support 206 and/or a substrate 202 thereon, disposed within the process chamber 200. As shown in FIG. 2, an array of radiant heating lamps 204 may be disposed below (i.e. facing the non-device side of) the substrate support 206. As shown in FIG. 2, an array of radiant heating lamps 204 may be disposed below and/or above the substrate support 206. The substrate support 206 may be a disk-like substrate support as illustrated, or may include a ring-like substrate support (not shown), which supports the substrate 202 from the edge of the substrate to expose a backside of the substrate 202 directly to heat from the radiant heating lamps 204. In embodiments, the substrate support 206 may be fabricated from silicon carbide or graphite coated with silicon carbide to absorb radiant energy from the lamps 204 and conduct the radiant energy to the substrate 202, thus heating the substrate 202.

The substrate support 206 may be located within the process chamber 200 between a first energy transmissive member 208, which may be a dome, and a second energy transmissive member 210, which may also or independently be a dome. The first energy transmissive member 208 and the second energy transmissive member 210, along with a body 212 which may be disposed between the first energy transmissive member 208 and second energy transmissive member 210, may generally define an internal region 211 of the process chamber 200. The first energy transmissive member 208 and/or the second energy transmissive member 210 may be convex and/or concave. In embodiments, The first energy transmissive member 208 and/or the second energy transmissive member 210 may be optically transparent to the high-energy radiant radiation (transmitting at least 95% of the radiation of the high-energy radiant radiation). In one embodiment, the first energy transmissive member 208 and the second energy transmissive member 210 are fabricated from quartz. In embodiments, the array of radiant heating lamps 204 may be disposed above the first energy transmissive member 208, for example, a region 239 defined between the first energy transmissive member 208 and a reflector 254 (discussed in greater detail below). In embodiments, the array of the radiant heating lamps 204 may be disposed adjacent to and beneath the second energy transmissive member 210. The radiant heating lamps 204 may be independently controlled in zones in order to control the temperature of various regions of the substrate 202 as a process gas or vapor passes over the surface of the substrate 202, thus facilitating the deposition or doping of a material onto the device side 250 of the substrate 202. In embodiments, a deposited material may include elemental semiconductor materials such as silicon, doped silicon, germanium, and doped germanium; semiconductor alloys such as silicon germanium and doped silicon germanium; and compound semiconductor materials, including III-V materials, examples of which include nitrides, phosphides, and arsenides of aluminum, gallium, indium, and thallium, and mixtures thereof, and II-VI materials, examples of which include sulfides, selenides and tellurides of zinc, cadmium, and mixtures thereof.

The radiant heating lamps 204 may provide a total lamp power of between about 10 KW and about 60 KW, and are configured to heat the substrate 202, for example to a temperature within a range of about 200° C. to about 1,600° C. and/or according to any one or more of the process condition temperatures discussed in greater detail below. Each lamp 204 can be coupled to a power distribution board, such as printed circuit board (PCB) 252, through which power is supplied to each lamp 204. In one embodiment, the radiant heating lamps 204 are positioned within a housing 245 which is configured to be cooled during or after processing by, for example, using a cooling fluid introduced into channels 249 located between the radiant heating lamps 204. However in embodiments, it should be clear that other heating methods and apparatus may be used alone or in conjunction with heating lamps 204. Such as, in embodiments, a heated or cooled substrate support 206.

The substrate 202 is transferred into the process chamber 200 and positioned onto the substrate support 206 through a loading port (discussed in greater detail in regards to FIG. 1) formed in the body 212. A process gas inlet 214 and a gas outlet 216 are provided in the body 212.

In embodiments, the substrate support 206 may include a shaft or stem 218 that is coupled to a motion assembly 220. The motion assembly 220 may include one or more actuators and/or adjustment devices that provide movement and/or adjustment of the position of the stem 218 and/or the substrate support 206 within the internal region 211. For example, the motion assembly 220 may include a rotary actuator 222, as an example, that rotates stem 218, and thus the substrate support 206, about the longitudinal axis A of the process chamber 200 perpendicular to an X-Y plane of the process chamber 200. The motion assembly 220 may also include a vertical actuator 224 to move the stem 218, and thus substrate support 206, in the Z direction (e.g. vertically) within the process chamber 200. In embodiments, the motion assembly 220 optionally includes a tilt adjustment device 226 that is used to adjust the planar orientation of the substrate support 206 in the internal region 211. The motion assembly 220 optionally also may include a lateral adjustment device 228 that is utilized to adjust the positioning of the stem 218 and/or the substrate support 206 in the x-y plane of the process chamber 200 within the internal region 211. In embodiments, the motion assembly 220 may include a pivot mechanism 230.

The substrate support 206 is shown in an elevated processing position but may be lifted or lowered vertically by the motion assembly 220 as described above. For instance, the substrate support 206 may be lowered to a transfer position (below the processing position) to allow lift pins 232 to contact standoffs 234 on or above the second energy transmissive member 210. The stand-offs provide one or more surfaces parallel to the X-Y plane of the process chamber 200 and help to prevent binding of the lift pins 232 that may occur if the end thereof is allowed to contact the curved surface of the second energy transmissive member 210. The stand-offs 234 are made of an optically transparent material in embodiments, such as quartz, to allow energy from the lamps 204 to pass therethrough. The lift pins 232 may be suspended in holes 207 in the substrate support 206, and as the substrate support 206 is lowered and the bottom of the lift pins 232 engage the standoffs 234. Thus, in embodiments, further downward movement of the substrate support 206 may cause the lift pins 232 to engage the substrate 202 and hold it stationary as the substrate support 206 is further lowered, and thus support the substrate in a position spaced apart from the substrate support 206 for transfer thereof from the process chamber 200. A robot (as discussed in greater detail in FIG. 1) then enters the process chamber 200 to engage at least the underside of the substrate 202 and remove the substrate 202 therefrom though the loading port. A new substrate 202 may then be loaded onto the lift pins 232 by the robot, and the substrate support 206 may then be actuated up to the processing position to place the substrate 202 thereon, with its device side 250 facing up. The lift pins 232 may include an enlarged head allowing the lift pins 232 to be suspended in openings in the substrate support 206 when in the processing position. The substrate support 206, while located in the processing position, may divide the internal volume of the process chamber 200 into a processing region 236 above the substrate support 206, and a purge region 238 below the substrate support 206. The substrate support 206 may be rotated during processing, such as by rotary actuator 222, to minimize the effect of thermal and process gas flow spatial anomalies within the process chamber 200 and thus facilitates uniform processing of the substrate 202. In embodiments, the substrate support 206 may rotates at a speed a between about 5 RPM and about 100 RPM, such as between about 10 RPM and about 50 RPM, for example about 15 RPM to about 45 RPM.

Substrate temperature may be measured by sensors configured to measure temperatures at one or more locations on the substrate or along the bottom of the substrate support 206. The sensors may be pyrometers (not shown) disposed in ports formed in the housing 245. Additionally or alternatively, one or more sensors 253, such as a pyrometer, may be used to measure the temperature of the device side 250 of the substrate 202. For instance, a reflector 254 may be optionally placed outside the first energy transmissive member 208 to reflect infrared light that is radiating off the substrate 202 and redirect the energy back onto the substrate 202. The reflector 254 may be secured to the first energy transmissive member 208 using a clamp ring 256. The reflector 254 can be made of a metal such as aluminum or stainless steel, or other materials as known in the art. The sensors 253 can be disposed through the reflector 254 to receive radiation from the device side 250 of the substrate 202.

Process gas supplied from a process gas supply source 251 may be introduced into the processing region 236 through the process gas inlet 214 formed in the sidewall of the body 212. The process gas inlet 214 may direct the process gas in a generally radially inward direction (e.g. towards axis A of process chamber 200). As such, in embodiments, the process gas inlet 214 may be a side gas injector. The side gas injector may be positioned to direct the process gas across a surface of the substrate support 206 and/or the substrate 202. During a film formation process for forming a film layer of the substrate 202, the substrate support 206 may be located in the processing position, disposing substrate 202 in the processing region 236, thus allowing the process gas to flow generally along flow path 273 across the upper surface of the substrate support 206 and/or substrate 202. The process gas may exit the processing region 236 (such as along flow path 275) through the gas outlet 216 located on the opposite side of the process chamber 200 from the process gas inlet 214. Removal of the process gas through the gas outlet 216 may be facilitated by a vacuum pump 257 fluidly coupled to the internal region 211 as well as a system foreline (not shown).

Purge gas supplied from a purge gas source 262 may be introduced to the purge region 238 through a purge gas inlet 264 formed in the sidewall of the body 212. The purge gas inlet 264 may be disposed at an elevation below the process gas inlet 214. The purge gas inlet 264 may be configured to direct the purge gas in a generally radially inward direction. The purge gas inlet 264 may be configured to direct the purge gas in an upward direction. During a film formation process, the substrate support 206 may be located at a position such that the purge gas flows generally along flow path 265 across a back side of the substrate support 206. The purge gas may exit the purge region 238 (such as along flow path 266) and may be exhausted out of the process chamber through the gas outlet 216 located on the opposite side of the process chamber 200 as the purge gas inlet 264.

The process chamber 200 may further include a spot heating module 271. The spot heating module 271 may include one or more spot heaters 270 which may provide individual heating to one or more locations on substrate 202 during processing. For instance, in embodiments, cold spots may be formed on the substrate 202 at locations that the substrate 202 is in contact with the lift pins 232.

The above-described process chamber 200 can be controlled by a processor based system controller, such as controller 247, shown in FIG. 2. For example, the controller 247 may be configured to control flow of various precursor and process gases and purge gases from gas sources, during different operations of a substrate processing sequence. By way of further example, the controller 250 may be configured to control a firing of the spot heating module 271, predict an algorithm for firing the spot heating module 271, and/or encode or synchronize the operation of the spot heating module 271 with substrate rotation, feeding of gases, lamp operation, or other process parameters, among other controller operations. The controller 247 includes a programmable central processing unit (CPU) 252 that is operable with a memory 255 and a mass storage device, an input control unit, and a display unit (not shown), such as clocks, cache, input/output (I/O) circuits, and the like, coupled to the various components of the process chamber 200 to facilitate control of substrate processing in the process chamber 200. The controller 247 may further include support circuits 258. To facilitate control of the process chamber 200 described above, the CPU 252 may be one of any form of general-purpose computer processor that can be used in an industrial setting, such as a programmable logic controller (PLC), for controlling various chambers and sub-processors. The memory 255 may be in the form of computer-readable storage media that contains instructions, that when executed by the CPU 252, facilitates the operation of the process chamber 200. The instructions in the memory 255 may be in the form of a program product such as a program that implements the method of the present disclosure.

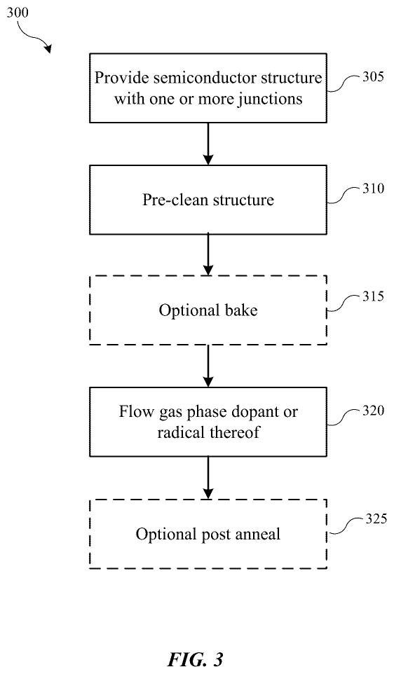

As noted above, the present technology may form a doped target region (which may be a silicon-containing material, in embodiments) utilizing gas phase doping. Turning to FIG. 3 is shown exemplary operations in a method 300 for forming a semiconductor structure according to embodiments of the present technology. Method 300 may include one or more operations prior to the initiation of the method, including front-end processing, deposition, etching, polishing, cleaning, or any other operations that may be performed prior to the described operations. For example, the method may begin after a number of layers have been deposited, such as for producing 3D DRAM structures. However, as explained above, it is to be understood that the figures illustrate just one exemplary process in which processes according to embodiments of the present technology may be employed, and the description is not intended to limit the technology to this process or structure alone. Some or all of the operations may be performed in chambers or system tools as previously described, or may be performed in different chambers on the same system tool, which may include the chamber in which the operations of method 300 may be performed.

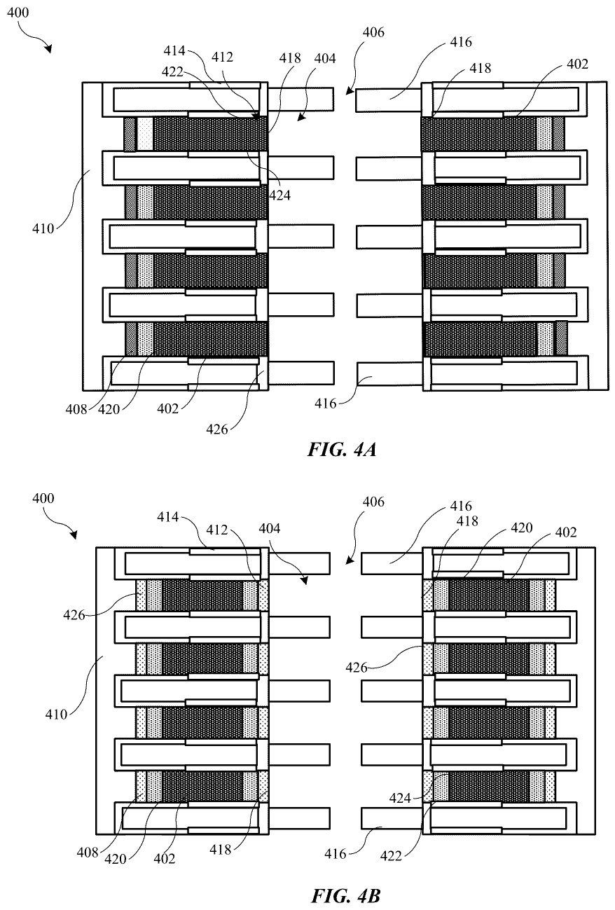

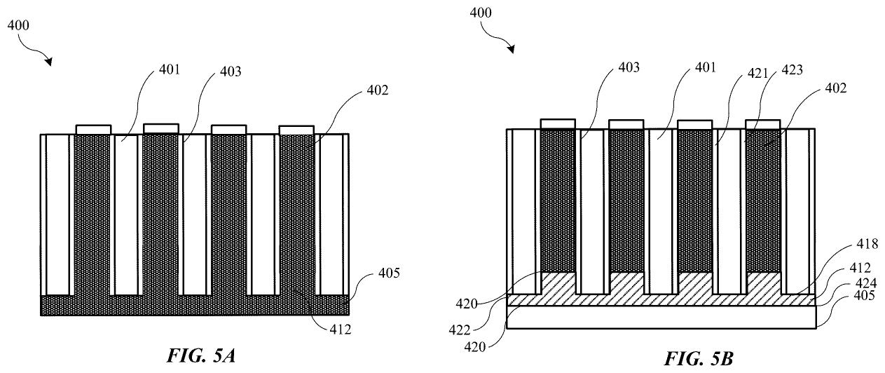

Method 300 may include a number of optional operations as illustrated, which may or may not be specifically associated with some embodiments of methods according to the present technology. For example, many of the operations are described in order to provide a broader scope of the structural formation, but are not critical to the technology, or may be performed by alternative methodology as will be discussed further below. Method 300 describes operations shown schematically in FIGS. 4A-4B and 5A-5B, the illustrations of which will be described in conjunction with the operations of method 300. It is to be understood that FIGS. 4A-4B and 5A-5B illustrate only partial schematic views, and a substrate may contain any number of structural sections having aspects as illustrated in the figures, as well as alternative structural aspects that may still benefit from operations of the present technology.

Method 300 may or may not involve optional operations to develop the semiconductor structure to a particular fabrication operation. It is to be understood that method 300 may be performed on any number of semiconductor structures 400, as illustrated in FIGS. 4A and/or 5A, including exemplary structures on which it is desired to form one or more doped regions. The doped regions are illustrated herein as being doped junctions. However, it should be understood that methods and systems discussed herein are also suitable for doping other desired regions. Nonetheless, as illustrated in FIGS. 4A and/or 5A a semiconductor structure 400 may have a number of layers of material deposited overlying the substrate. Semiconductor structure 400 may be formed from any number of materials, such as a base wafer or substrate made of silicon or silicon-containing materials, germanium, other substrate materials, as well as one or more materials that may be formed overlying the substrate during semiconductor processing.

Semiconductor structure 400 may illustrate a partial view of a stack of alternating layers of materials, which in some embodiments may be used in 3D DRAM memory formation (e.g. a structure as illustrated in FIG. 4A) or a vertically extending orientation, such as for 4F2 memory formation (e.g. as illustrated in FIG. 5A). As shown in FIG. 4A, semiconductor structure 400 may include one or more channels 402 extending between adjacent word lines 414. In FIG. 5A, one or more channels 402 may extend between adjacent features 401, and have protective liners 403 along the length of the channel 402. In embodiments, the one or more channels may be formed from one or more of silicon, polysilicon, amorphous silicon, doped silicon, strained silicon, silicon on insulator (SOI), carbon doped silicon dioxides, SiGe, germanium, gallium arsenide, GaN, InP, carbon nanotube, and any other materials such as III-IV group, 2D TMD metals, metal oxides, metal nitrides, metal alloys, and other conductive materials, combinations thereof, as well as other channel materials as known in the art. As the illustrated embodiment of FIG. 4A is a 3D DRAM structure, the one or more channels 402 may extend in a generally horizontal direction, and be generally perpendicular to an access hole or aperture 406 and/or bit line 410. Moreover, in the vertical orientation of FIG. 5A, the channels 402 may extend in a generally vertical direction and be generally perpendicular to the substrate 405. For instance, in embodiments, the one or more channels 402 may be within about 10° from perpendicular with memory hole 406 and/or substrate 405, such as less than or about 7.5°, such as less than or about 5°, such as less than or about 2.5°, such as less than or about 1° from perpendicular, or any ranges or values therebetween. In embodiments, the one or more channels 402 and the memory hole 406 may be perpendicular to one another.

However, while high aspect ratio and non-line-of sight structures have been so far discussed, it should be clear that the methods and systems discussed herein can also be used to form any semiconductor structure which has an access hole (e.g. contact hole). Thus, the present technology may be utilized replace conventional epitaxial doping or implant doping processes for doping target material (such as a Si-containing) exposed at the bottom of the respective hole. For example, methods and systems discussed herein may also suitable for junction doping of one or more bitline contacts or storage node contacts in current 6F2 DRAM or even junction doping for logic FinFET or Nanosheet transistors, to name a few.

In embodiments, the one or more channels 402 may have a depth of greater than or about 300 nm, such as greater than or about 400 nm, greater than or about 500 nm, greater than or about 600 nm, greater than or about 700 nm, or more, or any ranges or values therebetween. The one or more channels may have a width or critical dimension of greater than or about 5 nm, such as greater than or about 25 nm, greater than or about 50 nm, greater than or about 75 nm, greater than or about 100 nm, or more, or such as less than or about 50 nm, such as less than or about 40 nm, such as less than or about 30 nm, such as less than or about 25 nm, such as less than or about 20 nm, such as less than or about 15 nm, such as less than or about 10 nm, such as less than or about 5 nm, or any ranges or values therebetween. Thus, in embodiments, the channel (and/or adjacent features 401 of FIG. 5A) may be considered to have a high aspect ratio, such as an aspect ratio of greater than or about 50, such as greater than or about 60, such as greater than or about 70, such as greater than or about 80, such as greater than or about 90, such as greater than or about 100, such as greater than or about 110, such as greater than or about 120, such as greater than or about 130, such as greater than or about 140, such as greater than or about 150, or any ranges or values therebetween.

However, as discussed above, in embodiments, the one or more channels may not have a high aspect ratio or a large height. Instead, the channel may be located in a recess 404 as illustrated in FIG. 4A. For instance, as illustrated, such a recess 404 may block the line-of-sight to a plasma source, such as through memory hole 406. In embodiments, adjacent caps 416 may form all or a portion of the recess between adjacent channels 402, but the recess may be formed by any structure or feature as known in the art. Nonetheless, in embodiments, the one or more channels 402 may have any heights, widths, or aspect ratios discussed above, in combination with being disposed in a recess 404.

The semiconductor structure 400 may also include bit line junctions 408 adjacent to a bit line 410 and storage node junctions 412 adjacent to word lines 414, as illustrated in FIG. 4A. The bit line(s) 410 may extend in a first direction with may be a generally vertical direction, and one or more word lines may extend in a second direction, which may be orthogonal to bit line(s) 410 in embodiments. Nonetheless, as discussed above, the one or more channels 402 may extend in a direction that is generally orthogonal (e.g. within about 10° from orthogonal, such as less than or about 7.5°, such as less than or about 5°, such as less than or about 2.5°, such as less than or about 1° from orthogonal, or any ranges or values therebetween) to the first direction, the second direction, or both the first and second direction. However, it should be clear that FIGS. 4A-4B and/or 5A-5B are exemplary structures, and therefore, that the entire structure may be rotated, such that bit lines 410 extend in a generally horizontal orientation.

Nonetheless, as illustrated in FIG. 4A, the bit line junctions 408 may have already undergone junction doping, such as by the process discussed herein or by other processes as known in the art. However, in embodiments, bit line 410 may not yet be formed, and both bit line junctions 408 and storage node junctions 412 may be formed according to method 300. Nonetheless, as illustrated, storage node junctions 412 may not yet have undergone junction doping as illustrated in FIG. 4A.

Thus, in embodiments, methods according to the present technology may include providing a semiconductor structure 400 with one or more junctions 408 and/or 412 and/or one or more other undoped target regions, to a processing region of a processing chamber, such as one or more processing chambers 24 and/or 200 as discussed above, at operation 305. However, as discussed above, in embodiments, the semiconductor structure 400 may have one or more other regions where doping is desired. Such as one or more regions that are blocked from a plasma source, such as disposed within a recess 404 as illustrated in FIG. 4A, or disposed within a narrow and/or high aspect ratio feature 401 as illustrated in FIG. 5A.

Nonetheless, the present technology believes that any oxide present on the surface of the targeted doping region, even native oxide, partially or fully prevents gas phase doping. Namely, without wishing to be bound by theory, gas phase doping requires that the exposed surface, such as silicon in an example, be capable of dissolving the dopant present in the gas phase. Conversely, other processes, such as implants, deposition, and the like, may be capable of “forcing” the dopant through an oxide barrier, as the dopant is forced into pockets within the target surface, such as within the silicon surface. Thus, in embodiments, a pre-clean operation 310 may be necessary in order to utilize gas phase doping as discussed herein.

In embodiments, the pre-clean structure may be a wet or dry cleaning process, and may be an integrated pre-clean within the processing chamber. Alternatively, the semiconductor structure 400 may be transferred to a pre-clean chamber. However, in such an embodiments, the transfer may occurs without an air-break, such as within an oxygen free atmosphere. Thus, in embodiments, regardless of whether the pre-clean operation is integrated within the chamber, or is disposed in a separate chamber, the semiconductor structure may not be exposed to air or other oxygen sources after pre-clean operation 310 has commenced, or reduced levels of oxygen or air such that a continuous layer of native oxide, which could block dopant diffusion, to form or re-form. While any cleaning operations suitable for removing surface oxides may be utilized, in embodiments, a preclean, such as a Siconi™ clean may be utilized to remove any surface oxides present.

In embodiments, an optional hydrogen bake operation may be utilized at operation 315. In embodiments, such a hydrogen bake operation may not be necessary if adequate pre-cleaning is achieved at operation 310 and if no air-break has occurred. Nonetheless, in embodiments, it may be desirable to further ensure that little to no surface oxide is present in the targeted doping region. Thus, in optional embodiments, the semiconductor structure 400 may be subjected to a high temperature hydrogen bake. The hydrogen bake may include removing contaminants and defects on the surface of the semiconductor structure by flowing a hydrogen gas in conjunction with an elevated temperature of greater than or about 750° C., such as greater than or about 800° C., such as greater than or about 850° C., such as greater than or about 900° C., such as greater than or about 950° C., such as greater than or about 1000° C., such as greater than or about 1050° C., or any ranges or values therebetween.

Regardless of whether the optional bake operation 315 is utilized, the target region (e.g., storage node junction or region 412 in the illustrated embodiment), may contain less than or about 5 wt. % of total oxides, including native oxides, such as less than or about 4 wt. %, such as less than or about 3 wt. %, such as less than or about 2 wt. %, such as less than or about 1 wt. %, such as less than or about 0.5 wt. %, such a less than or about 0.1 wt. %, or be generally free of oxides, based upon the total weight of the targeted region.

Nonetheless, after the pre-clean operation 310 and optional bake operation 315, a dopant gas, also referred to as a gas phase dopant, may be flowed into the semiconductor structure for a soak process at operation 320 to dope the target regions, as illustrated in the now doped target regions/storage node junctions 412 of FIGS. 4B and/or 5B. The gas phase dopant or radicals that may be used in soak operation 320 may be or include any number of dopant gasses or radicals thereof. For example, any dopant gas suitable for depositing a doped material onto a target region, such as a silicon-containing material may be used. As non-limiting examples, in embodiments of the present technology the dopant gas may include phosphorous or boron, such as for forming doped source regions or drain regions. For example, the dopant gas may be or include phosphine (PH3), arsine (AsH3), nitrogen, (N2), ammonia (NH3), germane (GeH4), borane (BH3), diborane (B2H6), trimethyl gallium (Ga(CH3)3), aluminum chloride (AlCl3), trimethylaluminum (C6H15Al), radicals thereof, or combinations thereof.

The dopant gas may be flowed under high temperature conditions in order to improve the diffusion depth of the dopant into the target region. For instance, in embodiments, operation 320 may occur at temperatures of greater than or about 600° C., such as greater than or about 625° C., such as greater than or about 650° C., such as greater than or about 675° C., such as greater than or about 700° C., such as greater than or about 725° C., such as greater than or about 750° C., such as greater than or about 775° C., such as greater than or about 800° C., such as greater than or about 825° C., such as greater than or about 850° C., such as greater than or about 875° C., such as greater than or about 900° C., such as greater than or about 925° C., such as greater than or about 950° C., such as greater than or about 975° C., such as greater than or about 1000° C., or any ranges or values therebetween. However, it should be understood that, in embodiments, lower temperatures may be utilized. For instance, when utilizing radicals of any one or more of the above gas phase dopants or any other target dopant, lower temperatures, or no elevated temperature may be necessary due to the increase reactivity of the radicals.

In embodiments, the dopant gas may be soaked into the target region for a period of time of less than or about 5 minutes, such as less than or about 4 minutes, such as less than or about 3 minutes, such as less than or about 2 minutes, such as less than or about 90 seconds, such as less than or about 75 seconds, such as less than or about 60 seconds, such as less than or about 45 seconds, such as less than or about 30 seconds, such as less than or about 15 seconds, or such as greater than about 1 second, such as greater than or about 5 seconds, such as greater than or about 10 seconds, such as greater than or about 15 seconds, such as greater than or about 30 seconds, such as greater than or about 45 seconds, such as greater than or about 60 seconds, such as greater than or about 75 seconds, such as greater than or about 90 seconds, and/or up to about 15 minutes, 30 minutes, 45 minutes, or even greater than one hour in embodiments, or any ranges or values therebetween.

Namely, the present technology has found that the time and temperature may be tailored together to provide a highly controllable process. For instance, increased temperature may increase the penetration depth of the dopant into the target region at lower soak time periods. Alternatively, if a lower temperature is desired, a higher time period may be utilized to achieve the same or similar diffusion or penetration depths. Thus, in embodiments, any time and temperature may be utilized depending upon the desired doping levels and/or depths.

Additionally or alternatively, in embodiments, the semiconductor substrate may be subjected to the soaking for a period of time at a first temperature, and at least a second period of time at a second temperature. It should be clear that any number of temperatures and time periods may be utilized, including ramping the temperature from a starting temperature to a maximum temperature, pulsing the temperature, reverse ramping the temperature, and other temperature schemes as necessary for achieving the desired doping levels and depths. Moreover, in embodiments, each time period may be the same or may be different. Nonetheless, in embodiments the soaking operation may be conducted at a single temperature.

Thus, as illustrated in FIGS. 4B and/or 5B, in embodiments, the soak time and soak temperature may be selected so as to provide a diffusion depth from the exposed surface 418 to an interior edge 420 of the target region, of greater than or about 10 nm, such as greater than or about 20 nm, such as greater than or about 30 nm, such as greater than or about 40 nm, such as greater than or about 50 nm, such as greater than or about 60 nm, such as greater than or about 70 nm, such as greater than or about 80 nm, such as greater than or about 90 nm, such as greater than or about 100 nm, such a greater than or about 110 nm, such as greater than or about 120 nm, such as greater than or about 130 nm, such as greater than or about 140 nm, such a greater than or about 150 nm, or any ranges or values therebetween. As illustrated in FIG. 5B, in some structures, such as the high aspect ratio structure illustrated in FIGS. 5A and 5B, the exposed surface may be at a bottom 407 of feature 401 and the target region 412 may contain two interior edges 420. One interior edge 420 may be adjacent to substrate 405 and the second interior edge 420 may be within channel 402 at a height greater than the height of exposed surface 418. Thus, in regards to high aspect ratio structures, any of the above ranges may refer to a total depth from a first interior edge 420 to a second interior edge 420, or from exposed surface 418 to either or both inter edges 420. Additionally or alternatively, the depth may refer to any other doping orientations as known in the art, measured from the contact point of the target region with the gas phase dopant, to the point within the target region where no dopant is observed.

In addition, such penetration, or diffusion depths, may be exhibited while achieving a high doping concentration. For instance, a dopant concentration at a portion of the region most distal from exposed surface 418 (e.g. interior end 420 of storage node junction/target region 412 in the illustrated embodiment, where each storage node junction 412 in the illustrated embodiment defines a length from the exposed surface 418 to the interior end 420) which may have any one or more of the above depths may be greater than or about 1×10¹⁶ atom/cm³, such as greater than or about 5×10¹⁶ atom/cm³, such as greater than or about 1×10¹⁷ atom/cm³, such as greater than or about 2.5×10¹⁷ atom/cm³, such as greater than or about 5×10¹⁷ atom/cm³, such as greater than or about 7.5×10¹⁷ atom/cm³, such as greater than or about 1×10¹⁸ atom/cm³, such as greater than or about 5×10¹⁸ atom/cm³, such as greater than or about 1×10¹⁹ atom/cm³, or any ranges or values therebetween.

In addition, as illustrated in FIGS. 4B and/or 5B, the gas phase doping according to the present technology also results in a very even concentration of dopant across the entire width of the region (e.g. from first sidewall 422 to second sidewall 424 and/or from first liner 421 to second liner 423 in FIG. 5B), along the entire depth of the region (e.g. from exposed surface 418 to inner edge 420), or a combination thereof. Without wishing to be bound by theory, it is believed that the even distribution may be due at least in part to the fact that gas phase doping, as compared to deposition or implant processes, is based upon a thermal process where the diffusion rate is determined by the surface reaction rate, and is not dopant flux constrained unlike any plasma based processes. Thus, improved uniformity can be obtained according to the present technology by carefully controlling the process conditions, such as temperature. Thus, in embodiments, a layer 426 adjacent to exposed surface, or forming exposed surface 418, and/or any point along the depth of the region, may have a dopant concentration at any point along layer 426 or surface 418 that is greater than or about 50% of an average doping concentration of layer 426, such as greater than or about 60%, such as greater than or about 70%, such as greater than or about 80%, such as greater than or about 85%, such as greater than or about 90%, such as greater than or about 92.5%, such as greater than or about 95%, such as greater than or about 97.5%, such as greater than or about 99%, such as greater than or about 99.5% of the average doping concentration of layer 426 and/or surface 418.

However it should be understood that, when moving from exposed surface 418 to interior end 420 of the respective target region, a gradient of dopant is exhibited as shown in FIG. 4B. Thus, in embodiments, a layer 426 of the target region disposed adjacent to exposed surface 418 may have a concentration greater than the distal region adjacent to interior end 420. For instance, in embodiments, the layer 426 may have a dopant concentration of greater than or about 5×10¹⁸ atom/cm³, such as greater than or about 7.5×10¹⁸ atom/cm³, such as greater than or about 1×10¹⁹ atom/cm³, such as greater than or about 2.5×10¹⁷⁹ atom/cm³, such as greater than or about 5×10¹⁹ atom/cm³, such as greater than or about 7.5×10¹⁹ atom/cm³, such as greater than or about 1×10²⁰ atom/cm³, such as greater than or about 5×10²⁰ atom/cm³, such as greater than or about 1×10²¹ atom/cm³, or any ranges or values therebetween. However, in embodiments, as discussed above, the doping concentration may be substantially equal throughout the entire target region, according to any one or more of the concentrations discussed above.

While any pressure may be utilized as suitable in the art, in embodiments, operation 320 may be conducted at a pressure of greater than or about 50 torr, such as greater than or about 100 torr, such as greater than or about 150 torr, such as greater than or about 200 torr, such as greater than or about 250 torr, such as greater than or about 300 torr, such as greater than or about 350 torr, such as greater than or about 400 torr, such as greater than or about 450 torr, such as greater than or about 500 torr, such as greater than or about 550 torr, such as greater than or about 600 torr, or any ranges or values therebetween.

A flow rate for the dopant gas may be greater than or about 1 sccm, greater than or about 10 sccm, greater than or about 20 sccm, greater than or about 30 sccm, greater than or about 40 sccm, 50 sccm, greater than or about 100 sccm, greater than or about 250 sccm, greater than or about 500 sccm, greater than or about 750 sccm, greater than or about 1000 sccm, greater than or about 1250 sccm, greater than or about 1500 sccm, greater than or about 1750 sccm, greater than or about 2000 sccm, greater than or about 2250 sccm, greater than or about 2500 sccm, greater than or about 2750, greater than or about 3000 sccm, greater than or about 4000 sccm, greater than or about 5000 sccm, greater than or about 10000 sccm, or more, or any ranges or values therebetween. Additionally or alternatively, any flow rate may be utilized suitable for the selected gas phase dopant or radical thereof. A flow rate of the dopant gas may depend on the target doping concentration, as well as other process conditions such as temperature and pressure. However, compared to conventional doping processes, a lower dopant gas flow rate may be required due to the effects of the subsequent oxidation to be described herein.

In embodiments, an optional carrier gas may be utilized. The carrier gas may aid in the flow of the dopant gas and/or may help to maintain the oxygen free environment. Thus, in embodiments, the carrier gas may be an inert gas, such as one or more of helium, argon, molecular nitrogen (N₂), and molecular hydrogen (H₂), among other carrier gases.

As illustrated, the present technology provides for the doping of target regions utilizing a gentle, fast, and efficient process that does not result in waste of deposited or implanted materials. Moreover, the process of the present technology provides for a gas phase doping that does not require line-of-sight to the dopant source, and may therefore be utilized to dope features or target regions disposed between adjacent projecting features (e.g. within a recess), or within high aspect ratio and/or narrow features. Moreover, the process according to the present technology does not require a removal operation to remove a dopant carrier, reducing or eliminating the risk of damaging the feature or adjacent features, and reducing the amount of material that must be removed, that would previously been discarded.

Nevertheless, while the dopant gas soak alone may be sufficient to achieve the above reference depths and concentrations, in embodiments, it may be desirable to conduct an optional post anneal operation 325 to drive the dopant in, or further in, to the target feature. Annealing the semiconductor structure 400 can be accomplished by any suitable technique known in the art. For example, in an inert atmosphere, the annealing may occur in a temperature range of about 300° C. to about 1100° C., or such as greater than or about 350° C. greater than or about 400° C., greater than or about 450° C., greater than or about 500° C., greater than or about 550° C., greater than or about 600° C., greater than or about 650° C., greater than or about 700° C., greater than or about 750° C., greater than or about 800° C., greater than or about 850° C., greater than or about 900° C., greater than or about 950° C., greater than or about 1000° C., greater than or about 1050° C., or such as less than or about 1100° C., less than or about 1050° C., less than or about 1000° C., less than or about 950° C., less than or about 900° C., less than or about 850° C., less than or about 800° C., less than or about 750° C., less than or about 700° C., less than or about 650° C., less than or about 600° C., less than or about 550° C., less than or about 500° C., less than or about 450° C., less than or about 400° C., or any ranges or values therebetween.

Regardless of whether a post-anneal operation 425 is utilized, the semiconductor structure according to the now doped target region of the present technology may maintain the low oxide levels post doping. Thus, in embodiments, the doped target region (e.g., storage node junction/target region 412 in FIGS. 4B and/or 5B), may contain less than or about 5 wt. % of oxides, including native oxides, such as less than or about 4 wt. %, such as less than or about 3 wt. %, such as less than or about 2 wt. %, such as less than or about 1 wt. %, such as less than or about 0.5 wt. %, such a less than or about 0.1 wt. %, or be generally free of oxides, based upon the total weight of the targeted region, at one or more of the doping depths or concentrations discussed above.

Nonetheless, as discussed above, the method 300 according to the present technology is well suited for doping a target region disposed within a recess, such as recess 404. Namely, the present technology may provide for the doping of features that lack a linear path from the target region to a process gas source. In embodiments, the recess may be generally perpendicular to a second feature that does contain a linear path to a process gas source. Additionally or alternatively, the methods discussed herein may also be well suited for doping regions disposed within channels or features having any of the lengths, widths, and/or aspect ratios discussed in regards to channels 402 above, such a features and channels illustrated in FIG. 5B.

Moreover, while the present technology has found that the methods discussed herein are well suited as a stand-alone doping process, in embodiments, it may be advantageous to utilize the methods discussed herein in conjunction with one or more deposition, such as epitaxial growth processes, or implant doping processes. For instance, an epitaxial type process may be used before or after method 300 in order to create localized doping levels that are higher or lower than surrounding areas, or to introduce a second dopant, to name a few exemplary embodiments. In embodiments, the epitaxial step may begin after operation 320 and/or 325 (e.g. flow a dopant, and then begin flowing the epi precursors), or the epitaxial process may be utilized prior to method 300. Nonetheless, in embodiments, it should be understood that no additional doping processes are needed.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included.

As used herein and in the appended claims, the singular forms “a”, “an”, and “the” include plural references unless the context clearly dictates otherwise. Thus, for example, reference to “a material” includes a plurality of such materials, and reference to “the precursor” includes reference to one or more precursors and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

What is claimed is:

1. A semiconductor processing method comprising:
providing a high aspect ratio semiconductor structure within a semiconductor processing chamber, and wherein one or more undoped target regions are formed on the semiconductor structure;
subjecting the one or more undoped target regions to a pre-clean operation, removing at least a portion of any oxide present on the one or more undoped target regions;
contacting the one or more undoped target regions with a gas phase dopant or a radical thereof;
doping the one or more target regions.

2. The method of claim 1, wherein a temperature within the semiconductor processing chamber is maintained at greater than or about 600° C.

3. The method of claim 1, wherein less than or about 5 wt. % of total oxide remains in the target region subsequent the pre-clean operation, based upon a weight of the target region.

4. The method of claim 1, wherein the target region is disposed in a recess located within the semiconductor structure.

5. The method of claim 1, wherein the target region is disposed within a feature having a width of 10 nm or less.

6. The method of claim 1, wherein an oxygen free atmosphere is maintained within the semiconductor processing chamber during the pre-clean operation and/or during the contact with the gas phase dopant.

7. The method of claim 6, wherein the pre-clean operation is integrated into the semiconductor processing chamber.

8. The method of claim 1, wherein the gas phase dopant comprises phosphine (PH₃), arsine (AsH₃), nitrogen, (N₂), ammonia (NH₃), germane (GeH₄), borane (BH₃), diborane (B₂H₆), trimethyl gallium (Ga(CH₃)₃), aluminum chloride (AlCl₃), trimethylaluminum (C₆Hl₅Al), radicals thereof, or combinations thereof.

9. The method of claim 1, wherein the gas phase dopant is a phosphorus containing gas, a borane containing gas, radicals thereof, or combinations thereof.

10. The method of claim 1, further comprising doping all or a portion of the semiconductor structure with an epitaxial doping deposition or an implant prior to or subsequent the gas phase doping.

11. A semiconductor structure comprising:
at least one channel;
a junction disposed on an end of the channel, the junction comprising an exposed surface and an interior end adjacent to the channel, and a layer adjacent to the exposed surface, or forming exposed surface, wherein the layer comprises a dopant concentration at any point along layer or surface that is greater than or about 50% of an average doping concentration of the layer;
wherein the exposed surface has a doping level higher than a doping level of the interior end; and
wherein the channel is disposed adjacent to a feature having an aspect ratio of greater than or about 50 or a feature width of less than 10 nm, or wherein the at least one channel is disposed in a recess within the semiconductor structure.

12. The semiconductor structure of claim 11, wherein the exposed surface has a doping concentration of greater than or about 1×10¹⁹ atoms/cm³.

13. The semiconductor structure of claim 11, wherein the interior end has a doping concentration of greater than or about 1×10¹⁸ atoms/cm³.

14. The semiconductor structure of claim 11, wherein the junction defines a junction length between the exposed surface and the interior end, wherein the junction length is greater than or about 40 nm.

15. The semiconductor structure of claim 11, wherein the junction comprises less than or about 2 wt. % total oxides based upon a weight of the junction.

16. The semiconductor structure of claim 15, wherein the junction is substantially free of total oxides.

17. A memory device, comprising:
a bit line extending in a first direction;
two or more word lines extending in a second direction different than the first direction;
at least one channel extending between adjacent word lines in a direction orthogonal to the first direction and the second direction, the channel having a first end adjacent to the bit line and a second end opposite the first end, and
at least one junction disposed on the second end of the channel;
wherein the at least one junction comprises a dopant concentration of greater than or about 1×10¹⁸ atoms/cm³, and wherein the junction comprises less than or about 5 wt. % total oxides based upon a weight of the junction.

18. The memory device of claim 17, wherein the memory device comprises a 3D DRAM device.

19. The memory device of claim 17, wherein the memory device comprises a 4F2 device, wherein the junction is disposed adjacent to a feature having a width of less than or about 10 nm.

20. The memory device of claim 17, wherein the junction has a length from an exposed surface to an interior end of greater than or about 40 nm.
